(19) United States
(12) Patent Application Publication
(10) Pub. No.: US 2012/0018747 A1
(43) Pub. Date: Jan. 26, 2012

(54) LED LEAD FRAME AND METHOD OF MAKING THE SAME

(75) Inventors: ANDREW CHENG, New Taipei (TW); CHIH-PI CHENG, New Taipei (TW)

(73) Assignee: HON HAI PRECISION INDUSTRY CO., LTD., New Taipei (TW)

(21) Appl. No.: 13/187,515

(22) Filed: Jul. 21, 2011

(30) Foreign Application Priority Data
Jul. 21, 2010 (TW) 99123889

(51) Int. Cl. H01L 33/62; H01L 33/08; H01L 33/52

(52) U.S. Cl. 257/88; 257/99; 438/26; 257/E33.066

(57) ABSTRACT

An LED lead frame assembly comprises a wiring board having a plurality set of positive and negative poles arranged on a top surface thereof A plurality of LED chips are disposed on the wiring board, and electrically bonded to the bus line. A transparent cover is arranged upon the wiring board and covering the LED chip and the conductive lead.

### BACKGROUND OF THE INVENTION

1. Field of the invention

The present invention relates to an LED lead frame and a method of making the same, and more particularly to an LED lead frame in which the leads are interconnected by common bus lines so as to facilitating robust interconnection and overall configuration.

2. Description of Related Art

A typical LED usually includes a lead frame with a housing of concave cavity in which a LED chip is seated. At least two conductive leads are mounted in the lead frame to be connected to the LED chip. The lead is partially embedded in the housing with one end thereof exposed in the cavity and the other end extending out of the housing for being mounted to an external device. The conductive lead is preferably plated with silver so as to obtain better light-reflection performance and better conductivity. The concave cavity is filled with transparent sealing polymer after the LED chip is securely bonded in the cavity of the housing. The sealing polymer is in solid state in nature while becomes liquid after it is heated to a special high temperature.

The conventional LED lead frame has a pair of leads which are firstly produced by stamping a metal sheet and therein molded with a plastic housing. An LED chip is then bonded on one of the leads and electrically connected with the two leads by two wires. However, the above fabricating method is complex and the wire and leads need be made from noble metal, so the conventional LED lead frame resulting cost high.

Therefore, an improved LED lead frame is needed.

### SUMMARY OF THE INVENTION

An object of the present invention is to provide an LED lead frame in which the leads are interconnected by common bus lines so as to facilitating robust interconnection and overall configuration.

To achieve the aforementioned object, an LED lead frame assembly comprises at least a pair of bus lines arranged on a top surface. A LED chip is disposed on the wiring board, and electrically bonded to the bus lines. A transparent cover is arranged upon the wiring board and covering the LED chip.

To further achieve the aforementioned object, a method of making the LED lead frame assembly array comprises: providing a wiring board with a plurality of positive and negative poles, and a plurality of conductive leads, each conductive leads with two opposite ends, and one of the ends connected the positive or the negative poles. Providing a plurality of LED chips are disposed on the wiring board and being connected with the other ends of the conductive leads. Providing a plurality of transparent covers are arranged upon the wiring board, and each cover covering one LED chip and at least one conductive lead.

Other objects, advantages and novel features of the invention will become more apparent from the following detailed description of a preferred embodiment when taken in conjunction with the accompanying drawings.

### BRIEF DESCRIPTION OF THE DRAWINGS

FIG. 1 is an assembly, perspective view of a LED lead frame assembly in accordance with the present invention;

FIG. 2 is a partial exploded, perspective view of the LED lead frame assembly of FIG. 1;

FIG. 3 is an another partial exploded, perspective view of the LED lead frame assembly of FIG. 1;

FIG. 4 is perspective view of a cover of the LED lead frame assembly; and

FIG. 5 is a cross-section view taken along line 5-5 of FIG. 1.

### DETAILED DESCRIPTION OF THE INVENTION

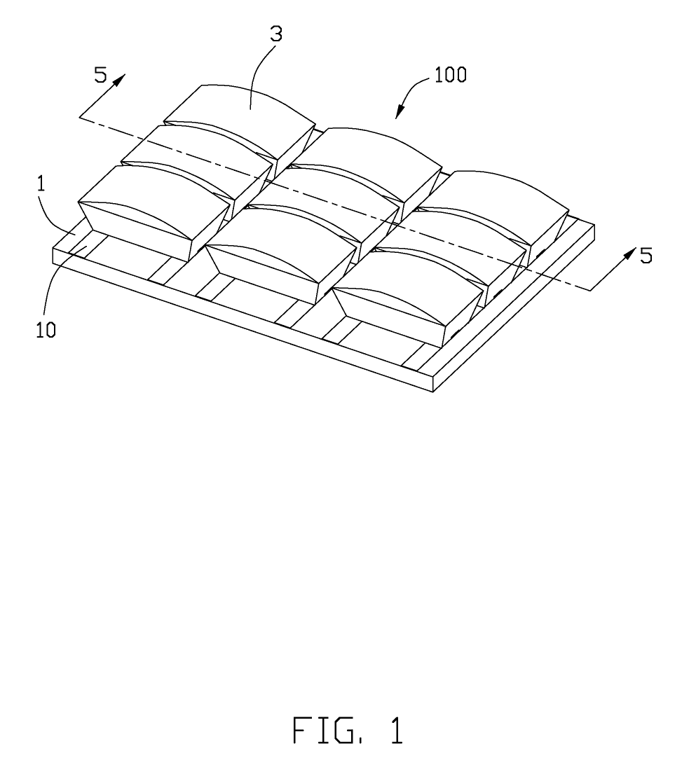

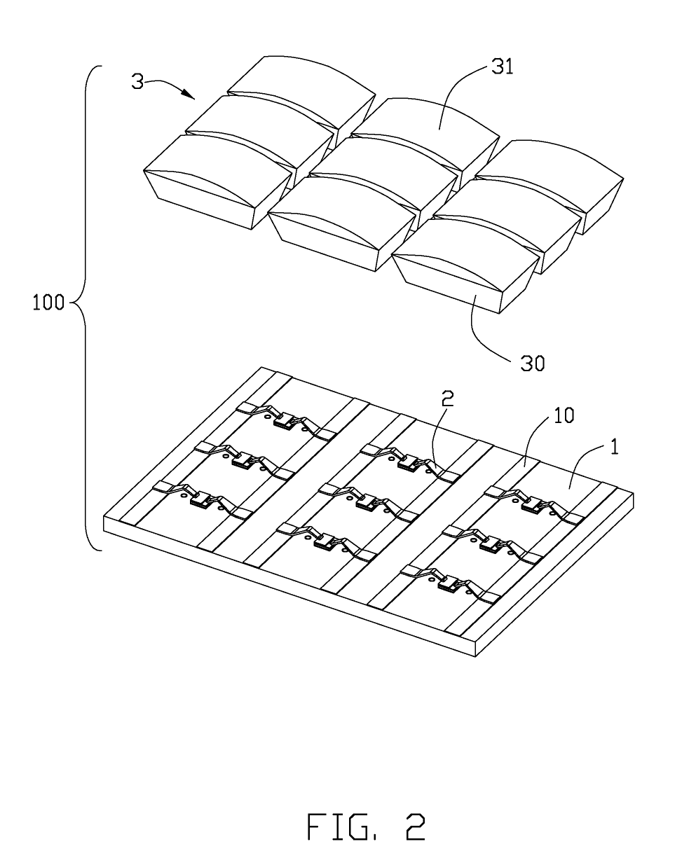

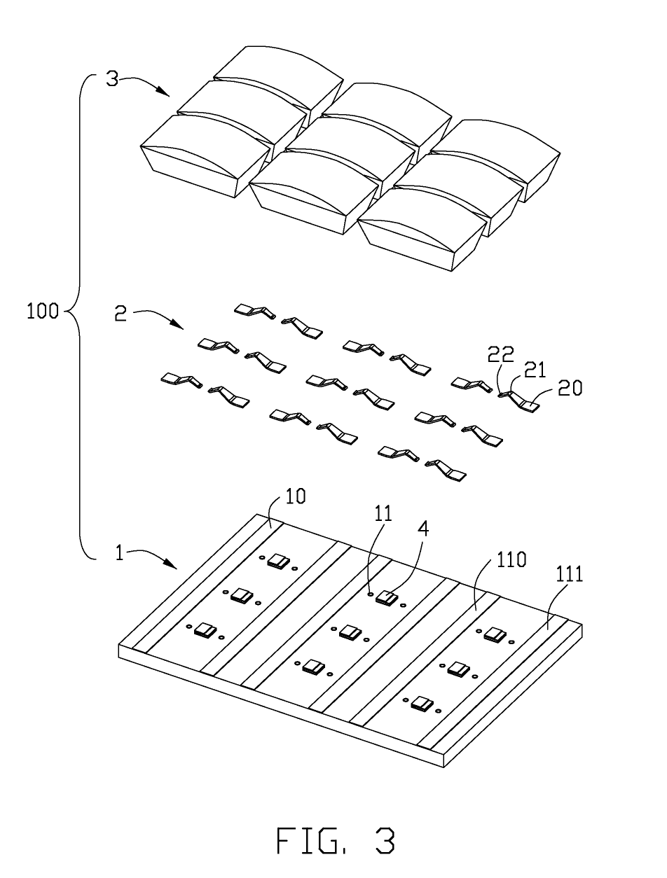

Referring to FIG. 1 to FIG. 3, an LED lead frame made in accordance with a preferable embodiment of the present invention is shown. The LED lead frame is used to connect an LED chip 4 and includes a planar wiring board 1 made of printed circuit board, a pair of contacts 2, and a cover 3 covered upon the board 1.

The top surface of the wiring board 1 is formed with a plurality of bus lines 10 by eroding. The bus lines 10 include a plurality of positive pole 110 and a plurality of negative pole 111, and the positive pole 110 and the negative pole 111 are arranged alternately on the top surface of the wiring board 1. The LED chip 4 is located between the positive pole 110 and the negative pole 111. Two through holes 11 are defined at opposite sides of the LED chip 4 on the wiring board 1.

The conductive leads 2 are formed by punching and soldered on the pole 10. Each conductive lead 2 includes a planar soldering portion 20, a bent portion 21 extending from the soldering portion 20 upwardly and then downwardly, and a contact portion 22 disposed at free end of the bent portion 21. A pair of contact portions 22 of the conductive leads 2 contact with one LED chip 4 on the wiring board 1 and a pair of the soldering portions 20 of the corresponding conductive leads 2 are soldered on the positive pole 110 and the negative pole 111, respectively.

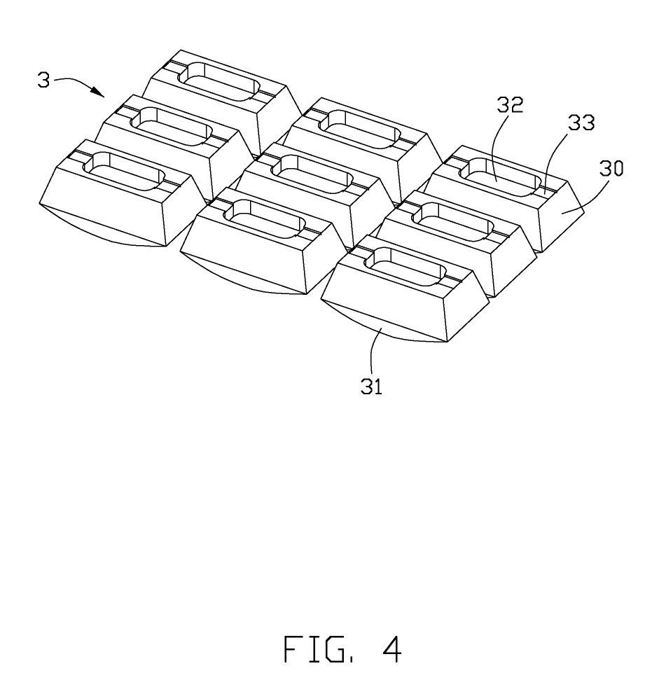

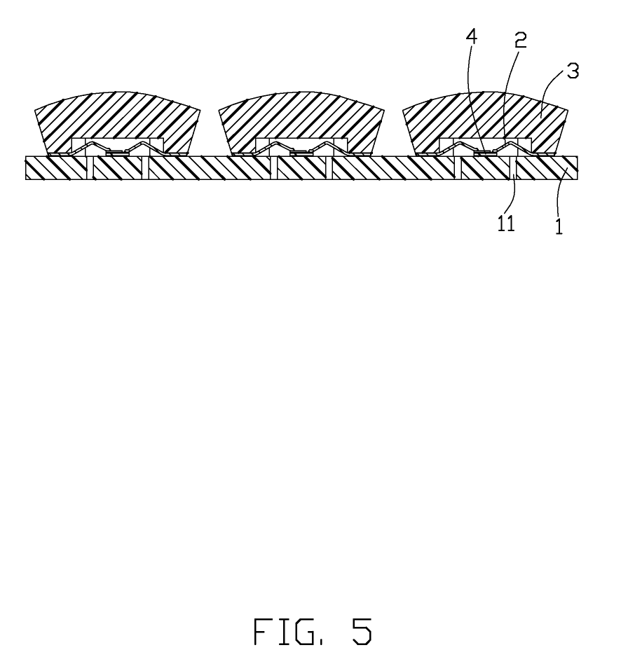

Referring to FIGS. 4 and 5, the cover 3 is made by transparent polymer for allowing the light to penetrate through. The cover 3 includes a main body 30 with a planar bottom surface and a curved top surface 31. A recess 32 is formed on the bottom surface of the main body 30 to receive the LED chip 4 and the bent portions 21 of the conductive leads 2. A pair of channels 33 are defined on the bottom surface of the main body 30 and communicated with the recess 32 and the outside environment for receiving the soldering portions 20 of the LED chip 4. Thus, the cover 3 is also used to protect the LED chip 4 and the conductive leads 2 according to above description.

The LED lead frame in the present invention is easy to be fabricated and assembled since has a reduced elements. The assembling process of the present LED lead frame needs to assembly the LED chip 4 and the conductive leads 2 on the wiring board 1 in turn. Then cover 3 is mounted in predetermined area upon the wiring board 1 by tool. Lastly, injects the transparent sealing plastic in liquid form into the recess 32 of the cover 3 via the through holes 11, and is then solidified under a lower temperature to seal and protect the LED chip 4.

Although the present invention has been described with reference to particular embodiments, it is not to be construed as being limited thereto. Various alterations and modifications can be made to the embodiments without in any way departing from the scope or spirit of the present invention as defined in the appended claims.

What is claimed is:

1. A LED lead frame assembly comprising:
a wiring board having a top surface;
at least a pair of bus lines arranged on a top surface;
a LED chip disposed on the wiring board, and electrically bonded to the bus lines; and
a transparent cover arranged upon the wiring board and covering the LED chip.

2. The LED lead frame assembly as claimed in claim 1, wherein the wiring board has a pair of through holes which are used as gates disposed at opposite sides of the LED chip.

3. The LED lead frame assembly as claimed in claim 1, further including a conductive lead electrically connected with the LED chip and the bus line.

4. The LED lead frame assembly as claimed in claim 3, wherein the conductive lead includes a planar soldering portion soldered on the positive or the negative pole, a bent portion extending from the soldering portion upwardly and then downwardly, and a contact portion disposed at free end of the bent portion and electrically connected on the LED chip.

5. The LED lead frame assembly as claimed in claim 4, wherein the cover includes a recess on a bottom surface thereof for receiving the LED chip, the contact portion and the bent portion of the conductive leads, and a pair of channels defined communicated with the recess and the outside environment for receiving the soldering portion conductive leads.

6. The LED lead frame assembly as claimed in claim 1, wherein the cover includes a main body with a planar bottom surface and a curved top surface.

7. The LED lead frame assembly as claimed in claim 5, wherein the main body has a recess on the bottom surface thereof to receive the LED chip and the conductive leads.

8. The LED lead frame assembly as claimed in claim 6, wherein a pair of channels are defined on the bottom surface of the main body and communicate the recess and the outside environment for receiving the conductive leads.

9. A method of making the LED lead frame assembly array comprising:
providing a wiring board with a plurality of positive and negative poles;
providing a plurality of conductive leads, each with two opposite ends, and one of the ends connected the positive or the negative poles;
providing a plurality of LED chips disposed on the wiring board and being connected with the other ends of the conductive leads; and
providing a plurality of transparent covers arranged upon the wiring board, and each cover covering one LED chip and at least one conductive lead.

10. The method of making the LED lead frame assembly as claimed in claim 9, wherein the conductive lead includes a planar soldering portion soldered on the positive or the negative pole, a bent portion extending from the soldering portion upwardly and then downwardly, and a contact portion disposed at free end of the bent portion and electrically connected on the LED chip.

11. The method of making the LED lead frame assembly as claimed in claim 9, wherein the cover includes a main body with a planar bottom surface and a curved top surface, and a recess and a pair of channels defined on the bottom surface.

12. The method of making the LED lead frame assembly as claimed in claim 9, wherein the LED chip is sealed by transparent sealing plastic via a through hole of the wiring board.

13. An LED lead frame assembly comprising:
a printed circuit board having conductive traces and LED chips thereon;
a plurality of leads respectively connecting to the corresponding chips and traces;
a transparent covers respectively covering the corresponding chips and leads.
